(19) United States
(12) Patent Application Publication
(10) Pub. No.: US 2025/0217549 A1
(43) Pub. Date: Jul. 3, 2025

(54) SYSTEM AND METHOD CONFIGURED TO UPDATE A SIMULATION MODEL USING A BLOCKCHAIN

(71) Applicant: Saudi Arabian Oil Company, Dhahran (SA)

(72) Inventor: Suleiman Khalid M Altaheini, Dhahran (SA)

(73) Assignee: Saudi Arabian Oil Company, Dhahran (SA)

(21) Appl. No.: 18/400,199

(22) Filed: Dec. 29, 2023

(51) Int. Cl. G06F 30/27

(52) U.S. Cl. CPC G06F 30/27

(57) ABSTRACT

A simulation model update system and method receive input data from a data source and receive simulation model data from a simulation model of a component of an organization. The simulation model generates the simulation model data from the input data. The received simulation model data is stored in a blockchain, and a recalibration module updates the simulation model when a metric value of the simulation model data exceeds a predetermined threshold value. A method implements the simulation model update system.

### FIELD OF THE DISCLOSURE

The present disclosure relates generally to updating a simulation model, and, more particularly, to a system and method configured to update a simulation model using a blockchain.

### BACKGROUND OF THE DISCLOSURE

In an organization such as an oil and gas company, simulation models are used to analyze aspects of operations of the organization. For example, in an oil and gas company, simulation models are built and maintained for an oil or gas-based reservoir accessed by rigs and wells.

As shown in FIG. 1, an example workflow 100 in the prior art illustrates how simulation models are built and maintained. The workflow 100 begins by receiving data in step 102, such as relevant exported data from the reservoir. The received data is gathered from a source or a database. The received data is then prepared and formatted in step 104 to be in a format suitable to be read by a simulation model. The workflow 100 then constructs a simulation model from the formatted data in step 106, and operates the constructed simulation model in step 108. The workflow 100 then checks in step 110 whether a time period between the last simulation model update and the current date of the simulation model is large. If the time period is large, the workflow 100 performs an update of the simulation model in step 112 by looping back to receive data during that time period in step 102. Updates to the simulation model are conducted after a set time period, such as semiannually. Alternatively, updates to the simulation model are conducted after a large or significant collection of relevant data. The frequency and nature of the updating is dependent on the organization, resources, and personnel in charge of maintaining the simulation model.

However, in step 110, if the time period is not large, then the workflow 100 checks whether the quality of the simulation model is poor in step 114. For example, the quality of the simulation model is poor if the output of the simulation model is not in line with historical or observed data. Referring to FIG. 1, if the quality is not poor, the workflow 100 continues to operate the simulation model in step 116, and loops back to step 110. However, if the quality of the simulation model is poor in step 114, then the workflow 100 performs a history match on the simulation model in step 118, calibrates the simulation model using the history-match data in step 120, and loops back to step 108 to operate the calibrated simulation model as a better representation of historical data.

Methods in the prior art are known to perform continuous calibration of a simulation model. However, such continuous calibration experiences operational inefficiencies and reduced quality when dealing with large simulation models. It is computationally and practically more optimal to have calibrations of simulation models performed when such calibrations are required instead of performing calibrations in a continuous manner. Other methods in the prior art update simulation models manually, which have a high chance of being neglected or have updates being postponed. Such manual updating results in incorrect results from the simulation model when used as studies that do not capture all up-to-date data.

### SUMMARY OF THE DISCLOSURE

According to an implementation consistent with the present disclosure, a system and method are configured to update a simulation model using a blockchain.

In an implementation, a simulation model update system comprises a communication interface, a hardware-based processor, a memory, and a set of modules. The communication interface is operatively connected to a data source and a simulation model module, the data source is configured to store input data, and the simulation model module is configured to store an operating parameter, to operate a simulation model, and to generate and output simulation model data from the input data and the operating parameter. The hardware-based processor is configured to receive the input data from the data source and to receive the simulation model data. The memory is configured to store instructions, configured to provide the instructions to the hardware-based processor, and configured to store the simulation model data in a blockchain. The set of modules is configured to implement the instructions provided to the hardware-based processor. The set of modules includes a recalibration module operatively connected to the simulation model module and configured, responsive to the simulation model data stored in the blockchain exceeding a predetermined threshold value, to update the simulation model.

The recalibration module can update the simulation model by changing the operating parameter, and the simulation model module can generate and can output updated simulation model data using the changed operating parameter, such that the updated simulation model data does not exceed the predetermined threshold value. The simulation model data can correspond to a performance parameter of a component of an organization. The performance parameter can be selected from the group consisting of: a quantitatively-matched parameter, a relatively-matched parameters, and a cumulatively-matched parameter. The simulation model module can implement the simulation model as a neural network configured by the operating parameter. The set of modules can further include a timer module configured to determine a passing of time dt, and the recalibration module can be responsive to the simulation model data stored in the blockchain exceeding the predetermined threshold value during the time dt to update the simulation model. The time dt can be a minimum update period. Alternatively, the time dt can be a maximum of a time required to obtain new input data from the data source and a time required to finish a cycle of processing the input data and running the simulation model.

In another implementation, a system comprises a data source, a simulation model module, and a simulation model update sub-system. The data source is configured to store input data corresponding to a component of an organization. The simulation model module is configured to store an operating parameter, to operate a simulation model of the component, and to generate and output simulation model data from the input data and the operating parameter. The simulation model update sub-system comprising a hardware-based processor, a memory, and a set of modules. The hardware-based processor is configured to receive the input data from the data source and to receive the simulation model data. The memory is configured to store instructions, configured to provide the instructions to the hardware-based processor, and configured to store the simulation model data in a blockchain. The set of modules is configured to implement the instructions provided to the hardware-based processor. The set of modules includes a recalibration module operatively connected to the simulation model module and configured, responsive to the simulation model data stored in the blockchain exceeding a predetermined threshold value, to update the simulation model.

The recalibration module can update the simulation model by changing the operating parameter, and the simulation model module can generate and output updated simulation model data using the changed operating parameter, such that the updated simulation model data does not exceed the predetermined threshold value. The simulation model data can correspond to a performance parameter of the component of the organization. The performance parameter can be selected from the group consisting of: a quantitatively-matched parameter, a relatively-matched parameter, and a cumulatively-matched parameter. The simulation model module can implement the simulation model as a neural network configured by the operating parameter. The set of modules can further include a timer module configured to determine a passing of time dt, and the recalibration module can be responsive to the simulation model data stored in the blockchain exceeding the predetermined threshold value during the time dt to update the simulation model. The time dt can be a minimum update period. Alternatively, the time dt can be a maximum of a time required to obtain new input data from the data source and a time required to finish a cycle of processing the input data and running the simulation model.

In a further implementation, a method comprises receiving input data corresponding to a component of an organization from a data source, operating a simulation model of the component using an operating parameter, generating simulation model data from the input data and the operating parameter, receiving the simulation model data, storing the simulation model data in a blockchain, and responsive to the simulation model data exceeding a predetermined threshold value, updating the simulation model.

The updating of the simulation model can include changing the operating parameter, and the simulation model module can generate updated simulation model data using the changed operating parameter, such that the updated simulation model data does not exceed the predetermined threshold value. The simulation model data corresponds to a performance parameter of a component of an organization, and the performance parameter is selected from the group consisting of: a quantitatively-matched parameter, a relatively-matched parameters, and a cumulatively-matched parameter. Operating the simulation model can comprise operating a neural network configured by the operating parameter.

Any combinations of the various embodiments, implementations, and examples disclosed herein can be used in a further implementation, consistent with the disclosure. These and other aspects and features can be appreciated from the following description of certain implementation presented herein in accordance with the disclosure and the accompanying drawings and claims.

### BRIEF DESCRIPTION OF THE DRAWINGS

FIG. 1 is a flowchart for updating a simulation model in the prior art.

FIG. 2 is a schematic of a system, according to an implementation.

FIG. 3 is a schematic of a blockchain used in the system of FIG. 2.

FIG. 4 is a schematic of a computing device used in the implementation.

FIGS. 5A-5B illustrate a flowchart of a method of updating a simulation model, according to the implementation.

FIG. 6 is a table of metrics used by the system of FIG. 2.

It is noted that the drawings are illustrative and are not necessarily to scale.

### DETAILED DESCRIPTION OF CERTAIN EMBODIMENTS OF THE DISCLOSURE

Example embodiments and implementations consistent with the teachings included in the present disclosure are directed to a system 200 and method 500 configured to update a simulation model using a blockchain.

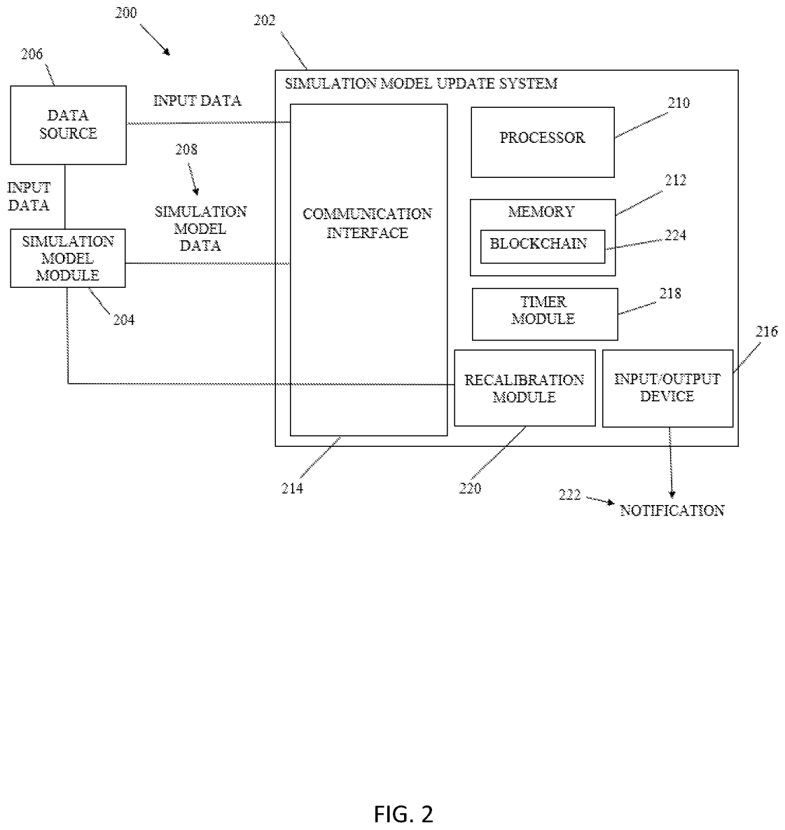

As shown in FIG. 2, the system 200 includes a simulation model update system 202 operatively connected to a simulation model module 204 and to a data source 206. The simulation model update system 202 is a sub-system of the system 200. For example, the simulation model update system 202 is operatively connected to the simulation model module 204 and to the data source 206 through a network. In one implementation, the network is the Internet. In another implementation, the network is an internal network or intranet of an organization. For example, the organization is an oil and gas company including at least one rig operating with a reservoir of oil or natural gas. In a further implementation, the network is a heterogeneous or hybrid network including at least the Internet and an intranet. The simulation model module 204 is operatively connected to the data source 206 through a network such as the Internet or an intranet. The simulation model module 204 stores at least one operating parameter. Using the at least one operating parameter and the input data received from the data source 206, the simulation model module 204 is configured to operate a simulation model. For example, the simulation model reflects an aspect of the organization. In one implementation, for an oil and gas company, the simulation model receives input data of a reservoir of oil or natural gas, and the simulation model reflects the received input data. For example, the input data from the data source 206 includes the performance data of the reservoir, and the simulation model of the simulation model module 204 reflects the performance of the reservoir based on the performance data. In one implementation, the simulation model generates simulation model data 208 from the input data. The simulation model module 204 outputs the simulation model data 208 to the simulation model update system 202.

In one implementation consistent with the invention, the simulation model update system 202 includes a hardware-based processor 210, a memory 212, a communication interface 214, an input/output device 216, and a set of modules 218-220. The memory 212 is configured to store data and instructions. In one implementation, the memory 212 includes at least one database configured to store the data. The memory 212 is configured to provide the instructions to the hardware-based processor 210. The communication interface 214 is configured to transmit data to and receive data from the simulation model source 204 and the data source 206. For example, the communication interface 214 receives the simulation model data from the simulation model module 204, and receives the input data from the data source 206. In one implementation, the communication interface 214 is operatively connected to the simulation model module 204 and the data source 206 through a network as described above.

The set of modules 218-220 is configured to implement the instructions provided to the hardware-based processor 210. The set of modules 218-220 include a timer module 218 and a recalibration module 220. The timer module 218 is configured to measure durations of time. For example, the timer module 218 includes a clock. In another example, the timer module 218 is incorporated into the processor 210. The recalibration module 220 is operatively connected to the simulation model module 204. In one implementation, the recalibration module 220 is operatively connected to the simulation model module 204 through the communication interface 214. The recalibration module 220 is configured to recalibrate, remediate, or update the simulation model of the simulation model module 220, as described below.

In one implementation, the input/output device 216 is configured to generate a notification 222 to a user. For example, the notification 222 is a visual message displayed on a display or monitor included in the input/output device 216. In another example, the notification 222 is an audio message output by a speaker included in the input/output device 216. In one implementation, the user is a system administrator. In another implementation, the user is a simulation model administrator or engineer. For example, the notification 222 is a message output to the simulation model administrator or engineer indicating that the simulation model maintained by the simulation model module 204 requires recalibration.

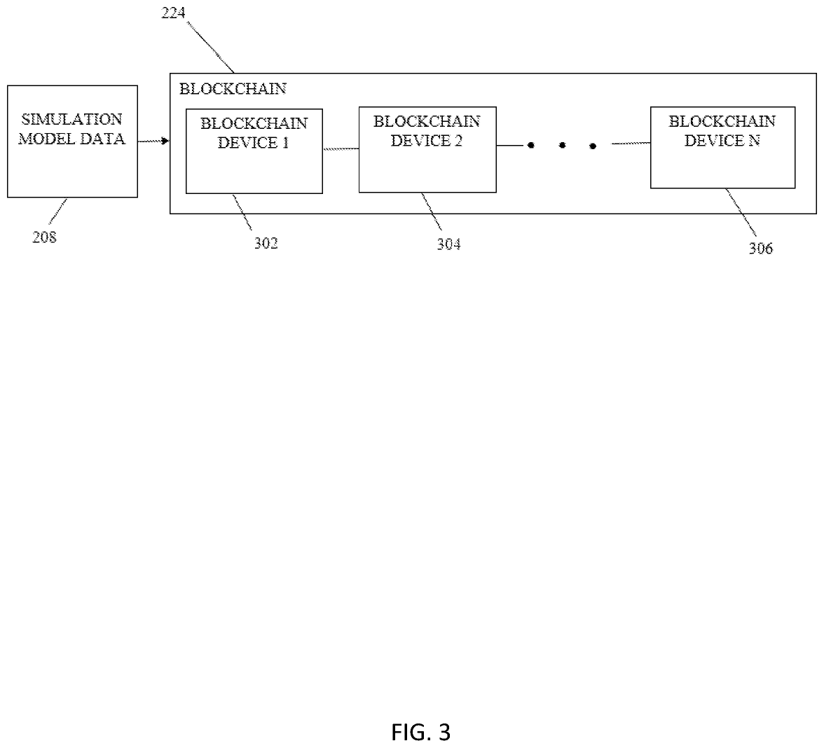

In one implementation, the memory 212 includes a database. For example, the memory 212 is configured to store data from the data source 206 in a database. In another example, the memory 212 is configured to store the simulation model data 208 in a database. In another implementation, the memory 212 includes a blockchain 224. As shown in FIG. 3, the blockchain 224 includes a plurality of blockchain devices 302, 304, 306 configured as a distributed ledger such that a growing list of stored records are securely linked together via cryptographic hashes. In one implementation, each blockchain device 302, 304, 306 is configured to store the at least one of the records in the list of records, and each blockchain device 302, 304, 306 includes a cryptographic hash of a previous block, a timestamp, and transaction date. In one implementation consistent with the invention, the blockchain 224 is configured to receive the simulation model data 208 output by the simulation model module 204. The blockchain 224 is configured to progressively add later generated simulation model data 208 output by the simulation model module 204 to subsequent block devices 304, 306 in the blockchain 224.

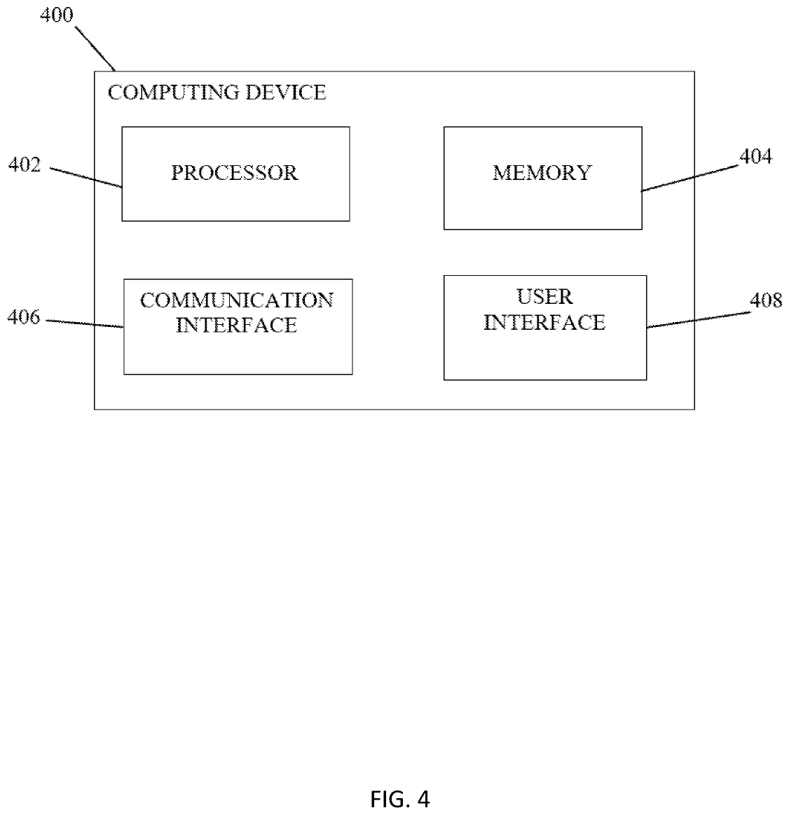

FIG. 4 illustrates a schematic of a computing device 400 including a processor 402 having code therein, a memory 404, and a communication interface 406. Optionally, the computing device 400 can include a user interface 408, such as an input device, an output device, or an input/output device. The processor 402, the memory 404, the communication interface 406, and the user interface 408 are operatively connected to each other via any known connections, such as a system bus, a network, etc. Any component, combination of components, and modules of the system 200 in FIG. 2 and the blockchain 300 in FIG. 3 can be implemented by a respective computing device 400. For example, each of the components shown in FIGS. 2-3 can be implemented by a respective computing device 400 shown in FIG. 4 and described below.

It is to be understood that the computing device 400 can include different components. Alternatively, the computing device 400 can include additional components. In another alternative implementation, some or all of the functions of a given component can instead be carried out by one or more different components. The computing device 400 can be implemented by a virtual computing device. Alternatively, the computing device 400 can be implemented by one or more computing resources in a cloud computing environment. Additionally, the computing device 400 can be implemented by a plurality of any known computing devices.

In one implementation consistent with the invention, the processor 402 is the processor 210 in FIG. 2. The processor 402 can be a hardware-based processor implementing a system, a sub-system, or a module. The processor 402 can include one or more general-purpose processors. Alternatively, the processor 402 can include one or more special-purpose processors. The processor 402 can be integrated in whole or in part with the memory 404, the communication interface 406, and the user interface 408. In another alternative implementation, the processor 402 can be implemented by any known hardware-based processing device such as a controller, an integrated circuit, a microchip, a central processing unit (CPU), a microprocessor, a system on a chip (SoC), a field-programmable gate array (FPGA), or an application-specific integrated circuit (ASIC). In addition, the processor 402 can include a plurality of processing elements configured to perform parallel processing. In a further alternative implementation, the processor 402 can include a plurality of nodes or artificial neurons configured as an artificial neural network. The processor 402 can be configured to implement any known artificial neural network, including a convolutional neural network (CNN).

In one implementation consistent with the invention, the memory 404 is the memory 212 in FIG. 2. The memory 404 can be implemented as a non-transitory computer-readable storage medium such as a hard drive, a solid-state drive, an erasable programmable read-only memory (EPROM), a universal serial bus (USB) storage device, a floppy disk, a compact disc read-only memory (CD-ROM) disk, a digital versatile disc (DVD), cloud-based storage, or any known non-volatile storage.

The code of the processor 402 can be stored in a memory internal to the processor 402. The code can be instructions implemented in hardware. Alternatively, the code can be instructions implemented in software. The instructions can be machine-language instructions executable by the processor 402 to cause the computing device 400 to perform the functions of the computing device 400 described herein. Alternatively, the instructions can include script instructions executable by a script interpreter configured to cause the processor 402 and computing device 400 to execute the instructions specified in the script instructions. In another alternative implementation, the instructions are executable by the processor 402 to cause the computing device 400 to execute an artificial neural network. The processor 402 can be implemented using hardware or software, such as the code. The processor 402 can implement a system, a sub-system, or a module, as described herein.

The memory 404 can store data in any known format, such as databases, data structures, data lakes, or network parameters of a neural network. The data can be stored in a table, a flat file, data in a filesystem, a heap file, a B+ tree, a hash table, or a hash bucket. The memory 404 can be implemented by any known memory, including random access memory (RAM), cache memory, register memory, or any other known memory device configured to store instructions or data for rapid access by the processor 402, including storage of instructions during execution.

In one implementation consistent with the invention, the communication interface 406 is the communication interface 214 of FIG. 2. The communication interface 406 can be any known device configured to perform the communication interface functions of the computing device 400 described herein. The communication interface 406 can implement wired communication between the computing device 400 and another entity. Alternatively, the communication interface 406 can implement wireless communication between the computing device 400 and another entity. The communication interface 406 can be implemented by an Ethernet, Wi-Fi, Bluetooth, or USB interface. The communication interface 406 can transmit and receive data over a network and to other devices using any known communication link or communication protocol.

The user interface 408 can be any known device configured to perform user input and output functions. In one implementation consistent with the invention, the user interface 408 is the input/output device 216 in FIG. 2. The user interface 408 can be configured to receive an input from a user. Alternatively, the user interface 408 can be configured to output information to the user. The user interface 408 can be a computer monitor, a television, a loudspeaker, a computer speaker, or any other known device operatively connected to the computing device 400 and configured to output information to the user. A user input can be received through the user interface 408 implementing a keyboard, a mouse, or any other known device operatively connected to the computing device 400 to input information from the user. Alternatively, the user interface 408 can be implemented by any known touchscreen. The computing device 400 can include a server, a personal computer, a laptop, a smartphone, or a tablet.

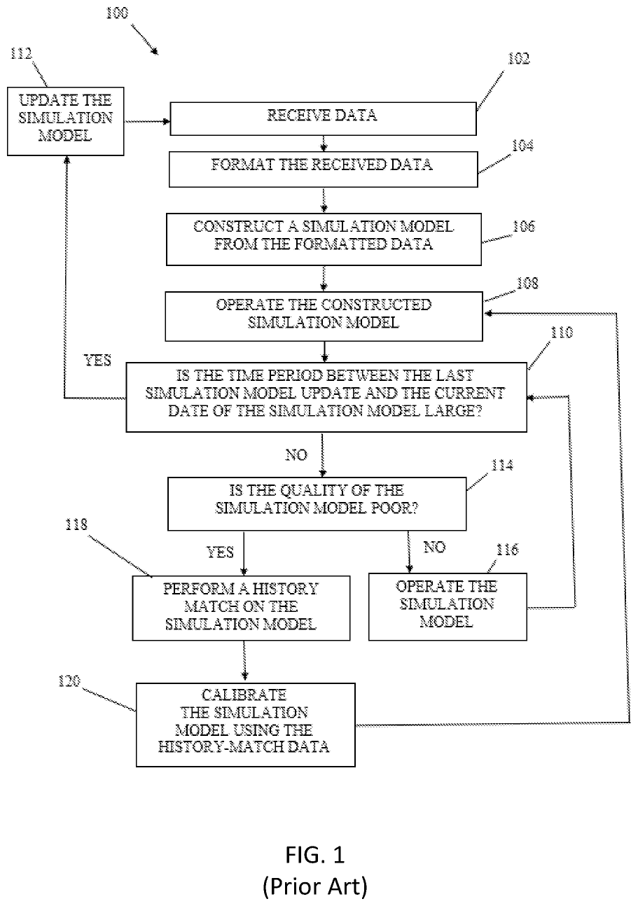

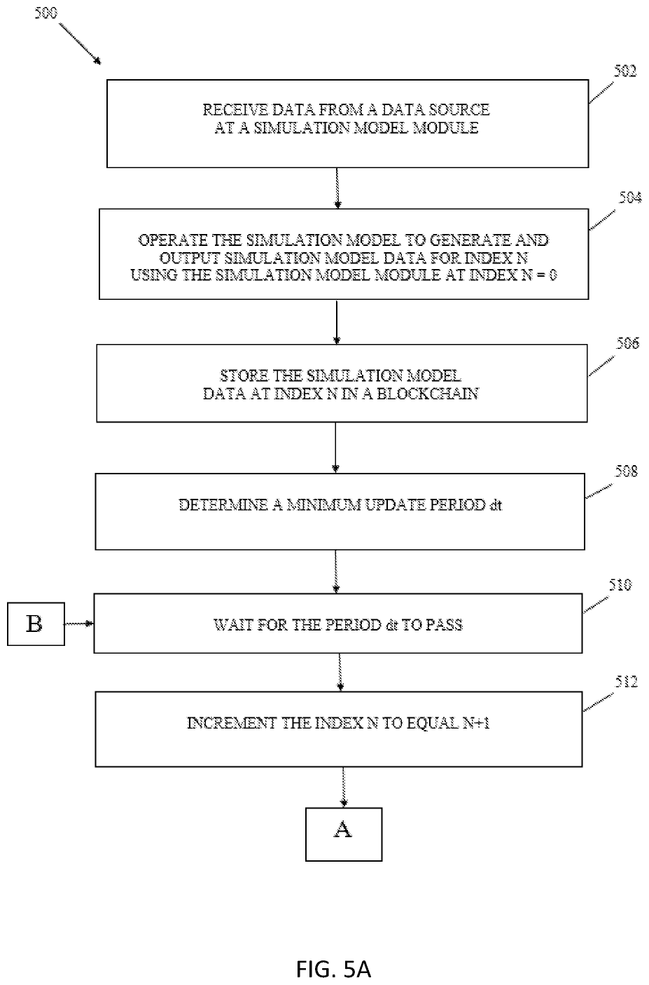

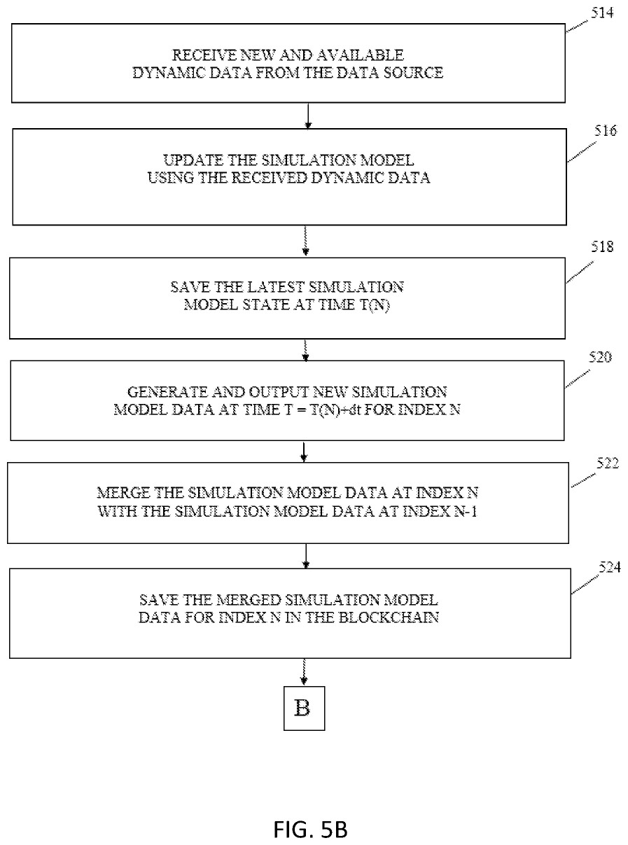

Referring to FIGS. 5A-5B, a method 500 is configured to update a simulation model maintained by the simulation model module 204. For example, the simulation model of the simulation model module 204 is initially built using the method 100 illustrated in FIG. 1. In an alternative example, the simulation model module 204 is built using any known simulation model creation tool or software application.

In one implementation consistent with the invention, once the simulation model is built, the method 500 automates the updating of the simulation model in steps 502-524. Referring to FIG. 5A, the method 500 receives data from the data source 206 in step 502. In one implementation, the data source 206 is a unified database hub associated with the organization operating the simulation model. In another implementation, the data source 206 includes a plurality of different data sources which communicate data directly to the simulation model update system 202. For example, by employing different data sources, the system 200 avoids any delays in waiting for data integration into a unified database hub of the system 200. In some implementations, different data sources obtain or provide data at different frequencies. In one implementation, the different frequencies include daily, weekly, monthly, annually, or any known regular period. In another implementation, the frequency of obtaining or providing data from a data source is aperiodic or irregular.

The method 500 then operates the simulation model in step 504 to generate and output the simulation model data 208. The outputted simulation model data 208 is received by the simulation model update system 202, for example, through the communication interface 214. The method 500 then stores the simulation model data at an index N in the blockchain 224 in step 506. The method 500 then determines a minimum update period dt in step 508. In one implementation, the update period dt is the smallest time period for a new simulation module update to be performed. For example, the update period dt is determined by the processor 210 which determines the update period dt from historical data of the availability of new dynamic data in the input data from the data source 206. In another example, the update period dt is a default time period, such as twenty-four hours for daily updates. In another implementation, the update period dt is set by a system administrator or a simulation model administrator or engineer using the input/output device 216. In a further implementation, the update period dt is set to be the maximum of the time required to obtain new data and the time required to finish a cycle of processing data and running the simulation model. Such a maximum value for the update period dt is used, for example, in the case when the processing time for exporting and preparing data updates and running the simulation model takes longer than the dt required to have new data updates. Accordingly, the update period dt is increased to avoid being in a non-ending cycle with backlogged data.

Such adjustments to the update period dt are performed to accommodate non-uniform data collection of data to be fed to the simulation model module 204 to operate the simulation model. For example, in an oil or natural gas simulation model, in large fields having hundreds of wells, acquisition of pressure surveys occur in an occasional manner and not in a systematic or established timeframe.

The method 500 then waits for the period dt to pass in step 510, with the waiting being timed using the timer module 218. Once the period dt has passed, the method 500 increments the index N to equal N+1 in step 512. The method 500 then receives any new and available dynamic data from the data source 206 in step 514. In the example of an oil or natural gas simulation model, the new and available dynamic data includes new well data from newly drilled wells, new completions, new well events, new rate values, new pressure values, seismic data, and geophysical data. In one implementation, the system 200 is responsive to a pause instruction to pause the updating of the simulation model by the recalibration module 220. For example, the pause instruction is generated automatically by the processor 210 until the processor 210 receives an indication of an arrival of the new dynamic data from the data source 206. In another example, the pause instruction is generated by an input or command from a system administrator or simulation model administrator or engineer through the input/output device 216. Accordingly, computational resources and computational power are not held up when waiting for the new dynamic data.

The method 500 then updates or recalibrates the simulation model in the simulation model module 204 using the received dynamic data in step 516. The recalibration module 220 performs the updating or recalibrating of the simulation model in step 516 automatically and in real-time using the received dynamic data. In one implementation, the recalibration module 220 calculates the metrics 600 from the received dynamic data from the data source 206. In another implementation, the processor 210 calculates the metrics 600 from the received dynamic data from the data source 206. In one implementation, such recalibration of the simulation model includes local calibration. In another implementation, the recalibration of the simulation model includes global calibration. In a further implementation, the recalibration of the simulation model includes history matching. The recalibration module 220 performs the updating or recalibration of the simulation model using a known recalibration method, such as a Kalman Filter, or other autonomous history-matching tools.

After setting up, building, and initializing a simulation model, the performance and output data of the simulation model is compared to observed historical data. In step 516, the simulation model is calibrated whereby the input data is modified to reduce the disagreement between the simulation model and the observed historical data. In one implementation, when the simulation model involves a reservoir in an oil or natural gas environment, the input data is mostly geological data in-between wells, and is generated through interpolation or kriging. Such kriging is a method of interpolation based on a Gaussian process governed by prior covariances. To perform the recalibration, such input data from the reservoir is modified to reduce the disagreement between the simulation model and the observed historical data for the reservoir.

In one implementation, the simulation model is a trained neural network stored in the simulation model module 204. The neural network includes a plurality of nodes or artificial neurons interconnected and configured in a plurality of layers. The plurality of layers include an input layer, an output layer, and at least one hidden layer between the input layer and the output layer. The simulation model module 204 stores a plurality of neural network parameters as the at least one operating parameter which define the topology and configuration of the neural network, including values representing the interconnections between nodes, and weight values associated with each interconnection between nodes. The recalibration module 220 performs the updating or recalibration of the simulation model by modifying at least one of the neural network parameters to increase the accuracy of the simulation model relative to the data from the data source 206. In another implementation, the simulation model is built, implemented, and recalibrated using any known simulation model technology.

In one implementation, to have a neural network perform as a simulation model, many simulation cases such as thousands of cases are used as a training set, whereby the neural network learns the relation between input and output data. In another implementation, the dimensionality of the simulation model is reduced for use by an autoencoder as the neural network configuration. Such an autoencoder learns how the simulation model operates, then indicates the output which the neural network needs in order to replicate the outputs by reconfiguring the input layer and/or the hidden layers as well as the weights of interconnections between the nodes or artificial neurons of the neural network.

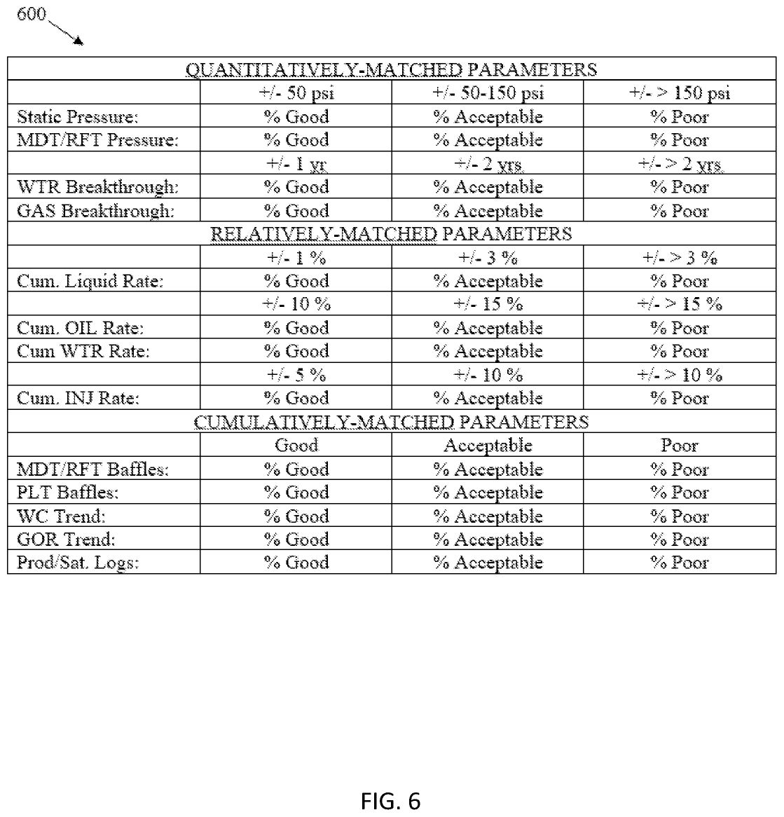

The recalibration module 220 uses predetermined metrics to determine whether the simulation model is performing within good or acceptable performance levels, or is performing poorly and needs recalibration to be updated. For example, as shown in FIG. 6, for a simulation model operating to evaluate an oil or natural gas reservoir, the metrics 600 include various quantitatively-matched parameters, various relatively-matched parameters, and various cumulatively-matched parameters of the reservoir. The metrics 600 of the various parameters are determined from data from the data source 206, such as performance values of oil or gas extraction equipment operating with the reservoir. The various parameters are measured as percentages of being good, being acceptable, or being poor. Such percentages shown in FIG. 6 act as operating thresholds used by the recalibration module 220 to control the recalibration of the simulation model.

For example, if the simulation model generates and outputs a predicted static pressure of about 30 psi, the output is “good” compared to an actual data value of 40 psi of the static pressure from the data source 206, since the predicted static pressure of about 30 psi is within +/−50 psi of the actual data value of 40 psi. However, when the simulation model generates and outputs a predicted static pressure of about 300 psi, the output is “poor” compared to an actual data value of 40 psi of the static pressure from the data source 206, since the predicted static pressure of about 300 psi is above +/−150 psi of the actual data value of 40 psi.

In one implementation consistent with the invention, the recalibration module 220 updates the simulation model by changing an operating parameter of the simulation model used by the simulation model module 204. The simulation model module 204 generates and outputs updated simulation model data 208 using the changed operating parameter so that a metric value of the updated simulation model data 208 does not exceed the predetermined threshold value. The recalibration module 220 determines the metric value of the simulation model data 208 using a predetermined metric and the input data from the data source 206. The predetermined metric compares the input data with the simulation model data 208 to generate the metric value. For example, the predetermined metric compares the input data with the simulation model data 208 by determining whether the simulation model data 208 is in a predetermined range of values corresponding to “good”, “acceptable” or “poor” performance. In the example above for static pressure, if the simulation model generates and outputs a predicted static pressure of about 30 psi, the output is “good” compared to an actual data value of 40 psi of the static pressure from the data source 206, since the predicted static pressure of about 30 psi is within +/−50 psi of the actual data value of 40 psi. However, when the simulation model generates and outputs a predicted static pressure of about 300 psi, the output is “poor” compared to an actual data value of 40 psi of the static pressure from the data source 206, since the predicted static pressure of about 300 psi is above +/−150 psi of the actual data value of 40 psi.

In another example, the predetermined metric compares the input data with the simulation model data 208 by determining a percentage difference between the input data and the simulation model data 208 relative to the input data. The recalibration module 220 compares the percentage difference to the predetermined threshold value to determine the case that the percentage difference exceeds the predetermined threshold value.

At step 516, in one implementation, when the recalibration module 220 performs the updating, in the case that a metric 600 in FIG. 6 determines a particular parameter to be in an “acceptable” range of values instead of being in the “good” range of values, the recalibration module 220 sends a notification signal to the input/output device 216. For example, the notification signal indicates that the particular parameter is trending to an unacceptable level, and so the system 200 predicts or forecasts when the model quality reduces to an unacceptable level. In response to the notification signal, the input/output device 216 generates and outputs a notification 222 indicating to a simulation model engineer to prepare resources ahead of time to perform model rebuilding or recalibration.

Referring back to FIG. 5, the method 500 then saves the latest simulation model state in the memory 212 in step 518. The method 500 then generates and outputs new simulation model data 208 using the updated simulation model at time t=t(N)+dt for current index N in step 520. The method 500 then merges the simulation model data at index N with the simulation model data at index N−1 in step 522. In one implementation, the merging in step 522 is performed by appending the simulation model data at index N to the simulation model data at index N−1. Alternatively, in step 522, the merging is performed by appending the simulation model data at index N−1 to the simulation model data at index N.

The method 500 then saves the merged simulation model data for index N in the blockchain 224 in step 524. In one implementation, real-time simulation models such as used in the system 200 include frequent and relatively short-duration simulation models. The system 200 preserves the simulation model data 208 including the merged simulation model data in the blockchain 224 to reduce computational demands on the system 200. In addition, the preservation of the simulation model data in the blockchain 224 allows a simulation model engineer or other users to view all historical and real-time results of the simulation models using the input/output device 216.

After step 524, the method 500 then loops back to step 510 to perform steps 510-524 in a cycle of automatically updating the simulation model maintained by the simulation model module 204.

Portions of the methods described herein can be performed by software or firmware in machine readable form on a tangible or non-transitory storage medium. For example, the software or firmware can be in the form of a computer program including computer program code adapted to cause the system to perform various actions described herein when the program is run on a computer or suitable hardware device, and where the computer program can be embodied on a computer readable medium. Examples of tangible storage media include computer storage devices having computer-readable media such as disks, thumb drives, flash memory, and the like, and do not include propagated signals. Propagated signals can be present in a tangible storage media. The software can be suitable for execution on a parallel processor or a serial processor such that various actions described herein can be carried out in any suitable order, or simultaneously.

It is to be further understood that like or similar numerals in the drawings represent like or similar elements through the several figures, and that not all components or steps described and illustrated with reference to the figures are required for all embodiments, implementations, examples, or arrangements.

The terminology used herein is for the purpose of describing particular implementations only and is not intended to be limiting of the invention. As used herein, the singular forms “a,” “an,” and “the” are intended to include the plural forms as well, unless the context clearly indicates otherwise. It will be further understood that the terms “contains”, “containing”, “includes”, “including,” “comprises”, and/or “comprising,” and variations thereof, when used in this specification, specify the presence of stated features, integers, steps, operations, elements, and/or components, but do not preclude the presence or addition of one or more other features, integers, steps, operations, elements, components, and/or groups thereof.

Terms of orientation are used herein merely for purposes of convention and referencing and are not to be construed as limiting. However, it is recognized these terms could be used with reference to an operator or user. Accordingly, no limitations are implied or to be inferred. In addition, the use of ordinal numbers (e.g., first, second, third) is for distinction and not counting. For example, the use of “third” does not imply there is a corresponding “first” or “second.” Also, the phraseology and terminology used herein is for the purpose of description and should not be regarded as limiting. The use of “including,” “comprising,” “having,” “containing,” “involving,” and variations thereof herein, is meant to encompass the items listed thereafter and equivalents thereof as well as additional items.

While the disclosure has described several exemplary implementations, it will be understood by those skilled in the art that various changes can be made, and equivalents can be substituted for elements thereof, without departing from the spirit and scope of the invention. In addition, many modifications will be appreciated by those skilled in the art to adapt a particular instrument, situation, or material to implementations of the disclosure without departing from the essential scope thereof. Therefore, it is intended that the invention not be limited to the particular implementations disclosed, or to the best mode contemplated for carrying out this invention, but that the invention will include all implementations falling within the scope of the appended claims.

The subject matter described above is provided by way of illustration only and should not be construed as limiting. Various modifications and changes can be made to the subject matter described herein without following the example embodiments, implementations, and applications illustrated and described, and without departing from the true spirit and scope of the invention encompassed by the present disclosure, which is defined by the set of recitations in the following claims and by structures and functions or steps which are equivalent to these recitations.

What is claimed is:

1. A simulation model update system, comprising:
a communication interface operatively connected to a data source and a simulation model module, wherein the data source is configured to store input data, and wherein the simulation model module is configured to store an operating parameter, to operate a simulation model, and to generate and output simulation model data from the input data and the operating parameter;
a hardware-based processor configured to receive the input data from the data source and to receive the simulation model data;
a memory configured to store instructions, configured to provide the instructions to the hardware-based processor, and configured to store the simulation model data in a blockchain; and
a set of modules configured to implement the instructions provided to the hardware-based processor, the set of modules including:
a recalibration module operatively connected to the simulation model module and configured, responsive to the simulation model data stored in the blockchain exceeding a predetermined threshold value, to update the simulation model.

2. The simulation model update system of claim 1, wherein the recalibration module updates the simulation model by changing the operating parameter,
wherein the simulation model module generates and outputs updated simulation model data using the changed operating parameter, and
wherein the updated simulation model data does not exceed the predetermined threshold value.

3. The simulation model update system of claim 1, wherein the simulation model data corresponds to a performance parameter of a component of an organization.

4. The simulation model update system of claim 3, wherein the performance parameter is selected from the group consisting of: a quantitatively-matched parameter, a relatively-matched parameters, and a cumulatively-matched parameter.

5. The simulation model update system of claim 1, wherein the simulation model module implements the simulation model as a neural network configured by the operating parameter.

6. The simulation model update system of claim 1, wherein the set of modules further includes:
a timer module configured to determine a passing of time dt, and
wherein the recalibration module, responsive to the simulation model data stored in the blockchain exceeding the predetermined threshold value during the time dt, to update the simulation model.

7. The simulation model update system of claim 6, wherein the time dt is a minimum update period.

8. The simulation model update system of claim 6, wherein the time dt is a maximum of a time required to obtain new input data from the data source and a time required to finish a cycle of processing the input data and running the simulation model.

9. A system, comprising:
a data source configured to store input data corresponding to a component of an organization;
a simulation model module configured to store an operating parameter, to operate a simulation model of the component, and to generate and output simulation model data from the input data and the operating parameter;
a simulation model update sub-system, comprising:
a hardware-based processor configured to receive the input data from the data source and to receive the simulation model data;
a memory configured to store instructions, configured to provide the instructions to the hardware-based processor, and configured to store the simulation model data in a blockchain; and
a set of modules configured to implement the instructions provided to the hardware-based processor, the set of modules including:
a recalibration module operatively connected to the simulation model module and configured, responsive to the simulation model data stored in the blockchain exceeding a predetermined threshold value, to update the simulation model.

10. The system of claim 9, wherein the recalibration module updates the simulation model by changing the operating parameter,
wherein the simulation model module generates and outputs updated simulation model data using the changed operating parameter, and
wherein the updated simulation model data does not exceed the predetermined threshold value.

11. The system of claim 9, wherein the simulation model data corresponds to a performance parameter of the component of the organization.

12. The system of claim 11, wherein the performance parameter is selected from the group consisting of: a quantitatively-matched parameter, a relatively-matched parameter, and a cumulatively-matched parameter.

13. The system of claim 9, wherein the simulation model module implements the simulation model as a neural network configured by the operating parameter.

14. The system of claim 9, wherein the set of modules further includes:
a timer module configured to determine a passing of time dt, and
wherein the recalibration module, responsive to the simulation model data stored in the blockchain exceeding the predetermined threshold value during the time dt, to update the simulation model.

15. The system of claim 14, wherein the time dt is a minimum update period.

16. The system of claim 14, wherein the time dt is a maximum of a time required to obtain new input data from the data source and a time required to finish a cycle of processing the input data and running the simulation model.

17. A method, comprising:
receiving, from a data source, input data corresponding to a component of an organization;
operating a simulation model of the component using an operating parameter;
generating simulation model data from the input data and the operating parameter;
receiving the simulation model data;
storing the simulation model data in a blockchain; and
responsive to the simulation model data exceeding a predetermined threshold value, updating the simulation model.

18. The method of claim 17, wherein the updating of the simulation model includes changing the operating parameter,
wherein the simulation model module generates updated simulation model data using the changed operating parameter, and
wherein the updated simulation model data does not exceed the predetermined threshold value.

19. The method of claim 17, wherein determining the simulation model data corresponds to a performance parameter of a component of an organization, wherein the performance parameter is selected from the group consisting of: a quantitatively-matched parameter, a relatively-matched parameters, and a cumulatively-matched parameter.

20. The method of claim 17, wherein operating the simulation model comprises:
operating a neural network configured by the operating parameter.
